(19) United States
(12) Patent Application Publication
(10) Pub. No.: US 2012/0292611 A1
(43) Pub. Date: Nov. 22, 2012

(54) ORGANIC LIGHT-EMITTING DISPLAY APPARATUS AND METHOD OF MANUFACTURING THE SAME

(75) Inventors: Seong-Kweon HEO, Yongin-City (KR); Mu-Gyeom KIM, Yongin-City (KR)

(73) Assignee: SAMSUNG MOBILE DISPLAY CO., LTD., Yongin-city (KR)

(21) Appl. No.: 13/443,406

(22) Filed: Apr. 10, 2012

(30) Foreign Application Priority Data
May 18, 2011 (KR) 10-2011-0046939

(51) Int. Cl. H01L 51/52; H01L 51/56

(52) U.S. Cl. 257/43; 438/34; 257/E51.018

(57) ABSTRACT

An organic light-emitting display apparatus including: a substrate; a thin-film transistor (TFT) formed on the substrate and including a gate electrode, a source electrode, a drain electrode, and an active layer; a first electrode formed on the substrate and electrically connected to the drain electrode; an intermediate layer formed on the first electrode and including an organic light-emitting layer; a second electrode formed on the intermediate layer; and an insertion layer formed between the first electrode and the intermediate layer and including an oxide.

### CROSS-REFERENCE TO RELATED PATENT APPLICATION

This application claims the benefit of Korean Patent Application No. 10-2011-0046939, filed on May 18, 2011, the disclosure of which is incorporated herein by reference for all purposes as if fully set forth herein.

### BACKGROUND OF THE INVENTION

1. Field of the Invention

One or more aspects of the present invention relate to an organic light-emitting display apparatus and a method of manufacturing the same.

2. Discussion of the Background

Among flat panel display apparatuses, an organic light-emitting diode (OLED) display apparatus is an emissive display that has a large viewing angle, excellent contrast, and a rapid response. Thus, OLED display apparatuses are drawing attention as the next-generation of display apparatus.

An OLED display apparatus includes an intermediate layer, a first electrode, and a second electrode. The intermediate layer includes an organic light-emitting layer. When a voltage is applied to the first and second electrodes, the organic light-emitting layer emits visible light.

Due to limitations on electrical characteristics, such as a limitation on recouping characteristics of electrons and holes in the organic light-emitting layer, a limitation on characteristics of effective voltage application to the first and second electrodes, and the like, image characteristics of the organic light-emitting display apparatus may deteriorate. Therefore, power consumption may be increased, in order to obtain a desired image quality. As a result, there is a need for an OLED display apparatus having stable and efficient electrical characteristics.

### SUMMARY OF THE INVENTION

One or more exemplary embodiments of the present invention provide an organic light-emitting display apparatus having improved electrical characteristics and a method of manufacturing the same.

Additional features of the invention will be set forth in the description which follows, and in part will be apparent from the description, or may be learned by practice of the invention.

According to an aspect of the present invention, there is provided an organic light-emitting display apparatus including: a substrate; a thin-film transistor (TFT) formed on the substrate and including a gate electrode, a source electrode, a drain electrode, and an active layer; a first electrode formed on the substrate and electrically connected to the drain electrode; an intermediate layer formed over the first electrode and including an organic light-emitting layer; a second electrode formed on the intermediate layer; and an insertion layer formed between the first electrode and the intermediate layer and includes an oxide.

According to another aspect of the present invention, there is provided a method of manufacturing an organic light-emitting display apparatus, the method including: forming a thin-film transistor (TFT) that includes a gate electrode, a source electrode, a drain electrode, and an active layer, on a substrate; forming a first electrode electrically connected to the drain electrode on the substrate; forming an intermediate layer including an organic light-emitting layer on the first electrode; forming a second electrode on the intermediate layer; and forming an insertion layer that is disposed between the first electrode and the intermediate layer and includes an oxide.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a schematic cross-sectional view of an organic light-emitting display apparatus according to an exemplary embodiment of the present invention.

FIGS. 2A, 2B, 2C, 2D, 2E, 2F, and 2G are schematic cross-sectional views sequentially illustrating a method of manufacturing the organic light-emitting display apparatus of FIG. 1, according to an exemplary embodiment of the present invention.

### DETAILED DESCRIPTION OF THE ILLUSTRATED EMBODIMENTS

The invention is described more fully hereinafter with reference to the accompanying drawings, in which exemplary embodiments of the invention are shown. This invention may, however, be embodied in many different forms and should not be construed as limited to the exemplary embodiments set forth herein. Rather, these exemplary embodiments are provided so that this disclosure is thorough, and will fully convey the scope of the invention to those skilled in the art. In the drawings, the size and relative sizes of layers and regions may be exaggerated for clarity. Like reference numerals in the drawings denote like elements.

It will be understood that when an element or layer is referred to as being “on” or “connected to” another element or layer, it can be directly on or directly connected to the other element or layer, or intervening elements or layers may be present. In contrast, when an element is referred to as being “directly on” or “directly connected to” another element or layer, there are no intervening elements or layers present.

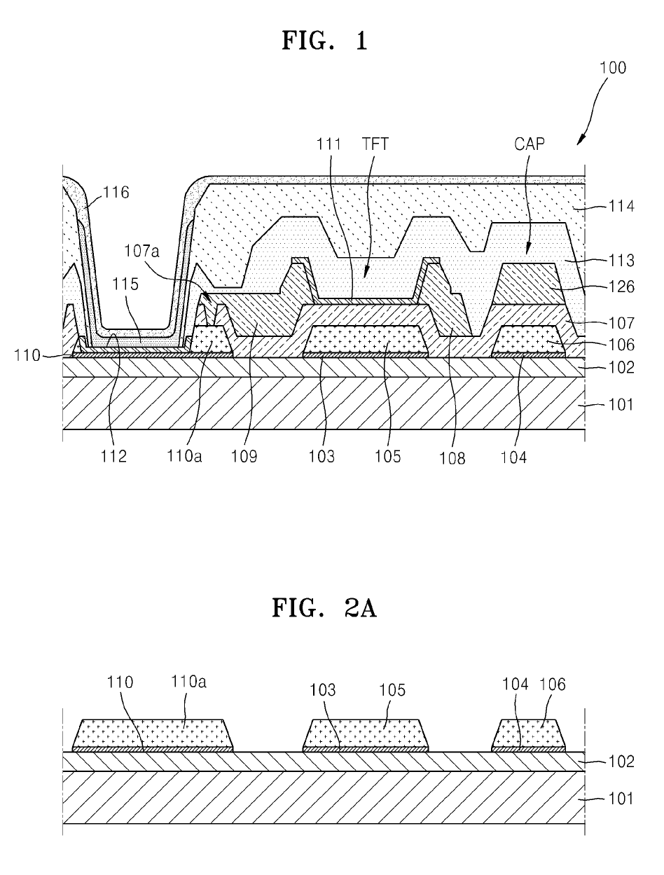

FIG. 1 is a schematic cross-sectional view of an organic light-emitting display apparatus 100 according to an embodiment of the present invention. Referring to FIG. 1, the organic light-emitting display apparatus 100 includes a substrate 101, a thin-film transistor (TFT), a first electrode 110, an intermediate layer 115, a second electrode 116, an insertion layer 112, and a capacitor CAP.

The TFT includes a gate electrode 105, a source electrode 108, a drain electrode 109, and an active layer 111. The capacitor CAP includes a first capacitor electrode 106 and a second capacitor electrode 126.

The substrate 101 may be a transparent substrate formed of a glass having silicon dioxide (SiO₂) as a main component. However, the substrate 101 is not limited thereto, and may also be formed of a transparent plastic formed from various organic materials.

A buffer layer 102 is formed on the substrate 101. The buffer layer 102 may contain silicon dioxide (SiO₂) or silicon nitride (SiNₓ). The buffer layer planarizes the substrate 101 and blocks the flow of moisture and/or foreign substances.

The first electrode 110, a first conductive pattern 103, and a second conductive pattern 104 are formed on the buffer layer 102. The first conductive pattern 103 and the second conductive pattern 104 may be formed of the same material as the first electrode 110. The first electrode 110 generally includes a transparent conductive material such as indium tin oxide (ITO).

The gate electrode 105 is formed on the first conductive pattern 103. The gate electrode 105 may include a metal or a metal alloy, such as molybdenum (Mo), molybdenum tungsten (MoW), an aluminum (Al) alloy, and the like. However, the gate electrode 105 is not limited thereto.

The first capacitor electrode 106 is formed on the second conductive pattern 104. The first capacitor electrode 106 may be formed of the same material as the gate electrode 105.

A conductive member 110a is disposed on the first electrode 110 and particularly, along an edge of the first electrode 110. The conductive member 110a contains the same material as the gate electrode 105.

A gate insulating layer 107 is formed on the gate electrode 105 and the first capacitor electrode 106. The gate insulating layer 107 includes an opening 107a through which a portion of the conductive member 110a is exposed.

The source electrode 108 and the drain electrode 109 are formed on the gate insulating layer 107. The drain electrode 109 is electrically connected to the first electrode 110. Specifically, the drain electrode 109 is connected to the conductive member 110a through the opening 107a. The source electrode 108 and the drain electrode may include a metal or a metal alloy, such as Mo, MoW, an Al alloy, and the like.

The second capacitor electrode 126 at least partially overlaps with the first capacitor electrode 106. The second capacitor electrode 126 may be formed of the same material as the source electrode 108 and the drain electrode 109.

The active layer 111 is a patterned layer formed on the source electrode 108 and the drain electrode 109. The active layer 111 extends from a side of the source electrode 108 to an opposing side of the drain electrode 109. The active layer 111 is also formed on an upper surface of the source electrode 108 and an upper surface of the drain electrode 109. The active layer 111 overlaps with the gate electrode 105.

The active layer 111 may contain an oxide semiconductor material. Specifically, the active layer 111 may contain gallium indium zinc oxide (GaInZnO) or hafnium indium zinc oxide (HfInZnO). The active layer 111 generally includes less than about 50 weight percent (wt %) indium (In) and Zinc (Zn), less than about 40 wt % gallium (Ga), and less than about 10 wt % hafnium (Hf).

The insertion layer 112 is formed on the first electrode 110. The insertion layer 112 may contain an oxide semiconductor material and, specifically, is formed of the same material as the active layer 111. That is, the insertion layer 112 contains GaInZnO or HfInZnO.

A passivation layer 113 is formed on the source electrode 108, the drain electrode 109, and the second capacitor electrode 126. The passivation layer 113 is formed to at least partially expose an upper surface of the insertion layer 112. The passivation layer 113 may include various insulating materials and protects the TFT.

A pixel-defining layer 114 is formed on the passivation layer 113. The pixel-defining layer 114 is formed to cover the passivation layer 113 and to at least partially expose an upper surface of the insertion layer 112.

The intermediate layer 115 may be formed on the exposed upper surface of the insertion layer 112. The intermediate layer 115 includes an organic light-emitting layer (not illustrated).

The second electrode 116 is formed on the intermediate layer 115. When a voltage is applied through the first electrode 110 and the second electrode 116, the organic light-emitting layer emits visible light.

A sealing member (not illustrated) may be disposed on the second electrode 116. The sealing member is formed to protect the intermediate layer 115 and other layers from external moisture and/or oxygen. The sealing member is formed of a transparent material. To this end, the sealing member may include multiple overlapping layers of glass, plastic, or organic and inorganic materials.

In the organic light-emitting display apparatus 100, the insertion layer 112 is disposed between the first electrode 100 and the intermediate layer 115. The insertion layer 112 contains GaInZnO or HfInZnO. GaInZnO or HfInZnO visible blue light or light having a wavelength shorter than visible blue light, according to the characteristics of an energy band, and then emits photoelectrons.

That is, when external light or light emitted from the intermediate layer 115 is radiated on the insertion layer 112, the insertion layer 112 emits photoelectrons. The photoelectrons facilitate the injection and transport of holes from the first electrode 110 to the intermediate layer 115. Particularly, when the first electrode 110 contains indium tin oxide (ITO), which has a low electrical conductivity, a barrier to the transport of holes is lowered, thereby decreasing a driving voltage for obtaining visible light from the organic light-emitting layer of the intermediate layer 115. As a result, brightness characteristics of the organic light-emitting display apparatus 100 are improved, and power consumption is decreased.

In the TFT, the source electrode 108 and the drain electrode 109 are formed on the gate electrode 105. The active layer 111 is formed on the source electrode and the drain electrode 109. That is, the active layer 111 is formed right after the source electrode 108 and the drain electrode 109 are formed, without having to additionally form an insulating layer. Accordingly, a bottom surface of the active layer 111 may be directly connected to the source electrode 108 and the drain electrode 109. Specifically, the active layer 111 contacts an upper surface and one side of both of the source electrode 108 and the drain electrode 109.

When compared to a structure of connecting the active layer 111 to the source/drain electrodes 108 and 109 through a contact hole, that is, a structure in which an insulating layer having a contact hole is formed between the active layer 111 and the source/drain electrodes 108 and 109, and the active layer 111 is connected to the source/drain electrodes 108 and 109, the width of the TFT of the apparatus 100 may be reduced.

Thus, the organic light-emitting display apparatus 100 may be designed to have improved efficiency and electrical characteristics. Furthermore, by minimizing an area in which the gate electrode 105 overlaps with the source electrode 108 and the drain electrode 109, a parasitic capacitance between the gate electrode 105 and the source/drain electrodes 108 and 109 may be reduced.

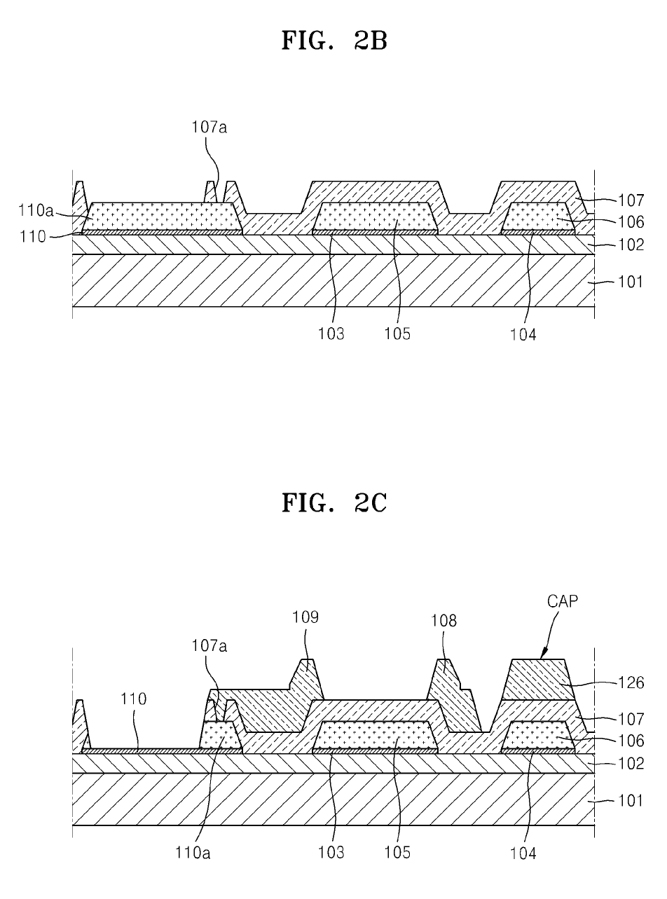

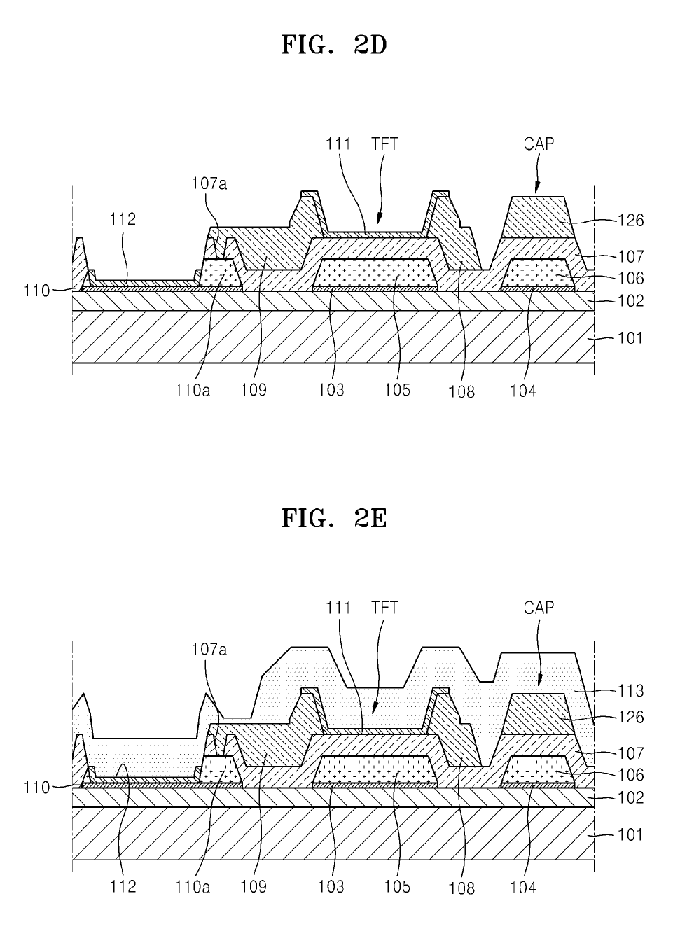

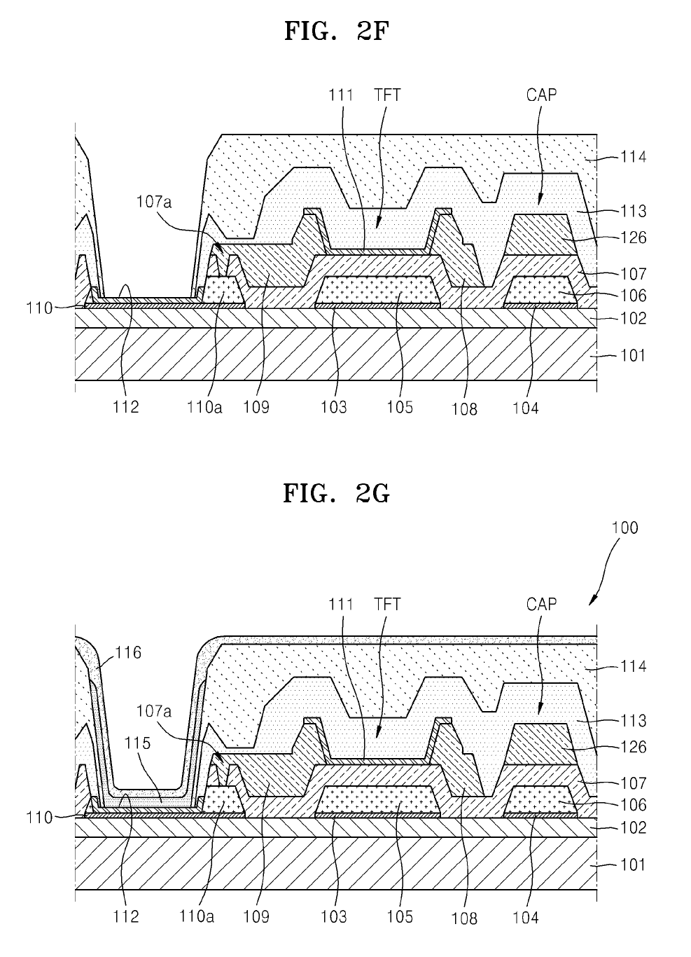

FIGS. 2A through 2G are schematic cross-sectional views sequentially illustrating a method of manufacturing the organic light-emitting display apparatus of FIG. 1, according to an exemplary embodiment of the present invention. Referring to FIG. 2A, a buffer layer 102 is formed on the substrate 101. A first electrode 110, a first conductive pattern 103, and a second conductive pattern 104 are formed on the buffer layer 102. A conductive member 110a is disposed on the first electrode 110. A gate electrode 105 is formed on the first conductive pattern 103. A first capacitor electrode 106 is formed on the second conductive pattern 104.

The first electrode 110, the first conductive pattern 103, and the second conductive pattern 104 are formed of the same material. The conductive member 110a, the gate electrode 105, and the first capacitor electrode 106 are formed of the same material.

A thin film containing a material for forming the first electrode 110, that is, ITO is formed on the buffer layer 102. Next, a thin film for containing a material for forming the gate electrode 105, i.e., a metal or a metal alloy such as Mo, MoW, or an Al alloy, is formed on the thin film formed on the buffer layer 102, without performing a patterning process. Then, the first electrode 110, the first conductive pattern 103, the second conductive pattern 104, the conductive member 110a, the gate electrode 105, and the first capacitor electrode 106 are formed, by performing one patterning process. As such, the patterning process may be performed using one mask.

Referring to FIG. 2B, a gate insulating layer 107 is formed on the gate electrode 105, the first capacitor electrode 106, and the conductive member 110a. The gate insulating layer 107 is formed to expose a portion of the conductive member 110a. That is, the gate insulating layer 107 is formed to expose a central portion of the conductive member 110a. The gate insulating layer 107 includes an opening 107a. A portion of the conductive member 110a is exposed through the opening 107a.

Referring to FIG. 2C, the source electrode 108 and the drain electrode 109 are formed on the gate insulating layer 107. The first electrode 110 is exposed by removing a portion of the conductive member 110a. The portion of the conductive member 110a may be removed while simultaneously patterning the source electrode 108 and the drain electrode 109.

The drain electrode 109 is connected to the conductive member 110a through the opening 107a. The drain electrode 109 is electrically connected to the first electrode 110 through the conductive member 110a. A second capacitor electrode 126 is formed to overlap with the first capacitor electrode 106. By doing so, a capacitor CAP is manufactured that includes the first capacitor electrode 106, the second capacitor electrode 126, and the gate insulating layer 107.

The second capacitor electrode 126 may be formed of the same material as the source electrode 108 and the drain electrode 109. The second capacitor electrode 126 is patterned simultaneously with the source electrode 108 and the drain electrode 109. That is, the source electrode 108, the drain electrode 109, and the second capacitor electrode 126 are formed simultaneously, using one mask.

Referring to FIG. 2D, an active layer 111 is formed on the source electrode 108 and the drain electrode 109. The active layer 111 is formed to overlap with the gate electrode 105. In addition, the active layer 111 is formed on a side of the source electrode 108 and an opposing side of the drain electrode 109. The active layer 111 is also formed on an upper surface of the source electrode 108 and an upper surface of the drain electrode 109. The active layer 111 contains an oxide semiconductor material. Specifically, the active layer 111 may contain GaInZnO or HfInZnO.

An insertion layer 112 is formed on the first electrode 110. The insertion layer 112 contains an oxide semiconductor material and, specifically, is formed of the same material as the active layer 111. That is, the active layer contains GaInZnO or HfInZnO.

A thin film containing a material for forming the active layer 111, that is, GaInZnO or HfInZnO, is formed on the source electrode 108, the drain electrode 109, and an upper part of the first electrode 110, through sputtering, without an additional mask. Then, the active layer 111 and the insertion layer 112 are simultaneously patterned using a mask. As such, the insertion layer 112 may be easily formed without using an additional mask or performing an additional patterning process.

Referring to FIG. 2E, a passivation layer 113 is formed on the source electrode 108, the drain electrode 109, the second capacitor electrode 126, and the insertion layer 112.

Referring to FIG. 2F, a pixel-defining layer 114 is formed on the passivation layer 113. The passivation layer 113 is patterned to at least partially expose an upper surface of the insertion layer 112. The pixel-defining layer 114 is formed to cover the passivation layer 113 and to at least partially expose the upper surface of the insertion layer 112. A patterning process may be performed to remove portions of the passivation layer 113 and the pixel-defining layer 114 that face the upper surface of the insertion layer 112.

However, the present invention is not limited to the patterning process described above, and may use various processes. For example, the patterning process may include removing a portion of the pixel-defining layer 114 that corresponds to an upper surface of the insertion layer 112, and then, removing a portion of the passivation layer 113 that corresponds to the upper surface of the insertion layer 112, by using a pattern of the pixel-defining layer 114 and without using an additional mask.

Referring to FIG. 2G, an intermediate layer 115 is formed on the exposed upper surface of the insertion layer 112. The intermediate layer 115 includes an organic light-emitting layer (not illustrated).

A second electrode 116 is formed on the intermediate layer 115. The second electrode 116 may be formed on all pixels (not illustrated) without having to perform an additional patterning process. A sealing member (not illustrated) may be disposed on the second electrode 116. The sealing member is formed to protect the intermediate layer 115 and other layers from external moisture and/or oxygen. The sealing member is formed of a transparent material and may include multiple layers of glass, plastic, or organic and inorganic materials.

The method of manufacturing the organic light-emitting display apparatus 100 includes forming the insertion layer 112 between the first electrode 110 and the intermediate layer 115. The insertion layer 112 and the active layer 111 are simultaneously patterned, without having to use an additional mask. As such, the insertion layer 112 is formed between the first electrode 110 and the intermediate layer 115, without a delay caused by the use of an additional process. Thus, brightness characteristics of the organic light-emitting display apparatus 100 are improved and the power consumption thereof is decreased.

The method of manufacturing the organic light-emitting display apparatus 100, according to the current exemplary embodiment, includes forming the first electrode 110, the gate electrode 105, and the first capacitor electrode 106 simultaneously, and forming the source electrode 108, the drain electrode 109, and the second capacitor electrode 126 simultaneously. Therefore, the manufacturing process may be simplified, and process defects may be minimized.

With regard to forming the passivation layer 113 and the pixel-defining layer 114, when the pixel-defining layer 114 is patterned and the passivation layer 113 is formed by using the pattern of the pixel-defining layer 114, an additional mask is not necessary for patterning the passivation layer 113. As such, the process is simplified. An organic light-emitting display apparatus and a method of manufacturing the same, according to aspects of the present invention, may produce improved electrical characteristics.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. An organic light-emitting display apparatus comprising:
a substrate;
a thin-film transistor (TFT) disposed on the substrate and comprising a gate electrode, a source electrode, a drain electrode, and an active layer;
a first electrode disposed on the substrate and electrically connected to the drain electrode;
an intermediate layer disposed on the first electrode and comprising an organic light-emitting layer;
a second electrode disposed on the intermediate layer; and
an insertion layer disposed between the first electrode and the intermediate layer and comprising an oxide.

2. The organic light-emitting display apparatus of claim 1, wherein the oxide comprises indium (In), Zinc (Zn), and gallium (Ga), or In, Zn, and hafnium (Hf).

3. The organic light-emitting display apparatus of claim 1, wherein the active layer comprises an oxide semiconductor material.

4. The organic light-emitting display apparatus of claim 1, wherein the active layer and the insertion layer comprise the same type of material.

5. The organic light-emitting display apparatus of claim 1, further comprising a first conductive pattern disposed between the substrate and the gate electrode, the first conductive pattern comprising the same type of material as the first electrode.

6. The organic light-emitting display apparatus of claim 5, wherein the first conductive pattern and the first electrode are disposed directly on the same layer.

7. The organic light-emitting display apparatus of claim 1, wherein:
the source electrode and the drain electrode are disposed on and insulated from the gate electrode, and
the active layer is disposed on the source electrode and the drain electrode.

8. The organic light-emitting display apparatus of claim 7, wherein the active layer:
faces the gate electrode; and
is disposed directly on a side of the source electrode, an opposing side of the drain electrode, an upper surface of the source electrode, and an upper surface of the drain electrode.

9. The organic light-emitting display apparatus of claim 1, further comprising a gate insulating layer disposed between the gate electrode and the source and drain electrodes, and
wherein the active layer is disposed directly on the gate insulating layer.

10. The organic light-emitting display apparatus of claim 1, further comprising a capacitor disposed on the substrate and comprising a first capacitor electrode and a second capacitor electrode, wherein,
the first capacitor electrode comprises the same type of material as the gate electrode, and
the second capacitor electrode comprises the same type of material as the source electrode, the drain electrode, or both the source electrode and the drain electrode.

11. The organic light-emitting display apparatus of claim 10, further comprising a second conductive pattern disposed between the substrate and the first capacitor electrode, the second conductive pattern comprising the same type of material as the first electrode.

12. A method of manufacturing an organic light-emitting display apparatus, the method comprising:
forming a thin-film transistor (TFT) on a substrate, the TFT comprising a gate electrode, a source electrode, a drain electrode, and an active layer;
forming a first electrode on the substrate and electrically connected to the drain electrode;
forming an intermediate layer on the first electrode and comprising an organic light-emitting layer;
forming a second electrode on the intermediate layer; and
forming an insertion layer, the insertion layer being disposed between the first electrode and the intermediate layer and comprising an oxide.

13. The method of claim 12, wherein the active layer and the insertion layer are simultaneously formed using the same type of material.

14. The method of claim 12, wherein the forming of the TFT and the forming of the first electrode comprise:
simultaneously forming the first electrode and the gate electrode through a patterning process.

15. The method of claim 12, further comprising:
forming a passivation layer on the TFT; and
forming a pixel-defining layer on the passivation layer.

16. The method of claim 15, wherein the passivation layer is patterned using the pixel-defining layer as a mask.
